(19) United States
(12) Patent Application Publication
(10) Pub. No.: US 2008/0081112 A1
(43) Pub. Date: Apr. 3, 2008

(54) Batch reaction chamber employing separate zones for radiant heating and resistive heating

(76) Inventors: Paul Brabant, Phoenix, AZ (US); Paul Jacobson, Phoenix, AZ (US)

Correspondence Address: KNOBBE, MARTENS, OLSEN & BEAR LLP, 2040 MAIN STREET, FOURTEENTH FLOOR, IRVINE, CA, 92614, US

(21) Appl. No.: 11/540,197

(22) Filed: Sep. 29, 2006

(51) Int. Cl. C23C 16/00; B05D 3/06

(52) U.S. Cl. 427/248.1; 427/545; 118/719; 118/725

(57) ABSTRACT

A reactor for processing a plurality of workpieces including a support for holding the plurality of workpieces, a first processing zone, one or more radiant heating elements adapted to heat a plurality of workpieces positioned in the first processing zone, a second processing zone, one or more resistive heating elements adapted to heat a plurality of workpieces positioned in the second processing zone, and an apparatus for moving the support between the first processing zone and the second processing zone.

### BACKGROUND OF THE INVENTION

1. Field of the Invention

The present invention relates generally to semiconductor processing equipment and specifically to batch reactors for semiconductor workpieces.

2. Description of the Related Art

High-temperature ovens, called reactors, are used to create layers that are patterned into structures of very fine dimensions, such as integrated circuits on semiconductor substrates. One or more substrates (or other types of workpieces), such as silicon wafers (which may or may not include previously formed structures thereon or therein), are placed on a substrate support inside the reaction chamber. The substrates are then heated to a desired temperature within the reaction chamber. In a typical treatment step, reactant gases are passed over the heated substrates, causing the chemical vapor deposition (CVD) of a thin layer on the substrates. Process conditions, particularly temperature uniformity and reactant gas distribution, must be carefully controlled to ensure high quality and uniformity of the deposited layers.

Through a series of process steps, including deposition, doping, photolithography, etching, and polishing, the starting substrates and the subsequent layers are converted into integrated circuits, with a single substrate producing from tens to thousands or even millions of integrated devices, depending on the sizes of the substrate and the circuits.

Batch processors have traditionally been employed in the semiconductor industry where possible to allow simultaneous processing of multiple substrates, thus economically providing low processing times and costs per substrate. For example, batch processes are often used in deposition, wet etch, ashing, and doping steps.

One process that often employs batch reactors is epitaxial deposition. A deposition is epitaxial if the deposited layer has the same crystallographic structure as the underlying silicon wafer. Through careful control of deposition conditions, reactant gases are passed over a heated substrate such that the deposited species precipitates in conformity with the underlying crystal structure, which is thus extended into the growing layer. The lowest level of devices, including transistors, often includes epitaxial layers formed over a single-crystal semiconductor substrate.

Because the purity and crystalline structure of the underlying substrate strongly affects the resulting epitaxial layer, it is important that the surface of the substrate is substantially free from contaminants such as carbon and oxygen. Contaminants can interfere with the crystal structure, and consequently the electrical properties, of each overlying layer as it is formed, resulting in a polycrystalline layer. Contaminant-free surfaces are also desirable for a number of applications other than epitaxial deposition.

One method of reducing contaminant levels is to clean the substrates prior to depositing the epitaxial layer, for example with Standard-Clean-1 (SC-1) and/or Standard-Clean-2 (SC2). Because an oxide-free surface is desired, after the cleaning step the substrate is typically dipped into an aqueous solution of hydrofluoric acid (HF) or treated with HF vapor to etch away the oxide layer remaining after the substrate cleaning. The HF etch typically leaves a monolayer of hydrogen on the surface of the substrate called “hydrogen termination.” The hydrogen terminated surface normally starts to reoxidize within about 20 minutes after the HF etch, reacting with moisture and oxygen (e.g., from the atmosphere) to form a thin layer (e.g., less than about 1 Å or approximately 10¹³ oxygen atoms/cm²) called a “sub-oxide.”

The sub-oxide is typically removed before epitaxial deposition in order to provide a substantially oxide-free surface to facilitate the epitaxial deposition. The sub-oxide can be removed by heating the substrate to between about 750 and 800° C. in a hydrogen environment, which is called a “hydrogen bake.” Epitaxial deposition is preferably performed at a temperature lower than about 750° C. in order to deposit a layer with the same crystallographic structure. Deposition at temperatures too high may disadvantageously consume thermal budget, but deposition at temperatures too low may result in undesirably long deposition durations.

Conventional batch reactors for epitaxial deposition use resistive heating to heat the substrates to the desired hydrogen bake and/or deposition temperatures. Such reactors have long heat-up and cool-down times on the order of hours. Typical temperature ramp-up rates are about 10 to 30° C./min and typical temperature cool-down rates are about 8 to 15° C./min for resistive heaters. Resistive heating provides fairly uniform temperature control of the substrates, which is desirable for epitaxial growth. Generally, the substrates are loaded into a substrate support within the reactor at a temperature low enough to preserve hydrogen termination (e.g., below about 527° C.), but at a temperature high enough to drive off moisture from the substrate support and the environment (e.g., above about 100° C.). After loading the substrates, the reactor temperature is raised to a temperature high enough to perform the hydrogen bake that removes the sub-oxide from the substrates (e.g., to between about 750 and 800° C.). After the hydrogen bake, the reactor is cooled to a temperature that will result in desirable epitaxial deposition, typically ranging from about 450 to 750° C., and then one or more material layers are deposited on the substrates. Sub-oxide formation can be limited during the time between the hydrogen bake and the deposition by not exposing the substrates to oxygen, for example by continuously purging the reactor with hydrogen gas.

### SUMMARY OF THE INVENTION

In one aspect, the present invention provides a reactor for processing a plurality of workpieces comprising a support for holding the plurality of workpieces, a first processing zone, one or more radiant heating elements adapted to heat a plurality of workpieces positioned in the first processing zone, a second processing zone, one or more resistive heating elements adapted to heat a plurality of workpieces positioned in the second processing zone, and an apparatus for moving the support between the first processing zone and the second processing zone.

In another aspect, the present invention provides a method of processing a plurality of workpieces comprising, providing the workpieces in a first processing zone, providing radiant heat to the workpieces in the first processing zone, processing the workpieces in the first processing zone, after processing the workpieces in the first processing zone, moving the workpieces to a second processing zone, providing resistive heat to the workpieces in the second processing zone, and processing the workpieces in the second processing zone.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

These and other features, aspects, and advantages of the invention disclosed herein are described below with reference to the drawings of preferred embodiments, which are intended to illustrate and not to limit the invention. The drawings comprise two figures in which:

FIG. 1 illustrates one embodiment of a batch reactor employing separate zones for radiant heating and resistive heating.

FIG. 2 is an exemplary process chart of a process performed in a conventional batch reactor and a process performed in the batch reactor of FIG. 1.

### DETAILED DESCRIPTION OF THE PREFERRED EMBODIMENTS

Although certain preferred embodiments and examples are disclosed below, it will be understood by those in the art that the invention extends beyond the specifically disclosed embodiments and/or uses of the invention and obvious modifications and equivalents thereof. Thus, it is intended that the scope of the invention herein disclosed should not be limited by the particular disclosed embodiments described below.

Epitaxial deposition is desirably performed on an oxide-free surface, so the workpieces are typically heated to a temperature greater than 527° C. (e.g., to about 750-800° C.) prior to deposition in order to hydrogen bake them, thereby removing sub-oxide and preparing the surface for deposition. Hydrogen termination is removed if the workpieces increase to a temperature greater than about 527° C. The surfaces of the workpieces are highly reactive and vulnerable to oxidation when not hydrogen terminated. Thus, removing the sub-oxide with a hydrogen bake also removes the hydrogen termination, leaving the workpiece surfaces highly reactive. Additionally, the duration in this state of high reactivity is long when resistive heaters are used because the durations needed to heat the workpieces to the hydrogen bake temperature and to cool the workpieces to the deposition temperature, during which the workpieces are highly reactive, are limited to heating rates of about 10 to 30° C. per minute (° C./min) and cooling rates of about 8 to 15° C./min for resistive heating. Conventional reactors also have a very difficult time controlling oxygen and carbon contamination of the highly reactive workpiece surfaces during these long temperature ramping durations.

Radiant heating provided by radiant heating elements provides rapid heating and quick cooling of workpieces. In some embodiments, radiant heating elements provide heating rates of about 180 to 220° C./min and cooling rates of about 40 to 60° C./min. However, radiant heating elements typically do not provide the temperature uniformity desired for processes such as epitaxial deposition. At least one aspect of the present invention is the recognition that a reactor with separate zones for resistive heating and radiant heating can provide rapid heating and cooling of workpieces while also providing fairly uniform temperature control. Workpieces can be rapidly heated in a radiant heating zone to perform a process that does not require a high degree of temperature uniformity, then rapidly cooled in the radiant heating zone, and then moved to a resistive heating zone to perform a process for which temperature uniformity is desirable. Such a reactor thereby exploits the advantages of both types of heating without suffering from the drawbacks of either type of heating.

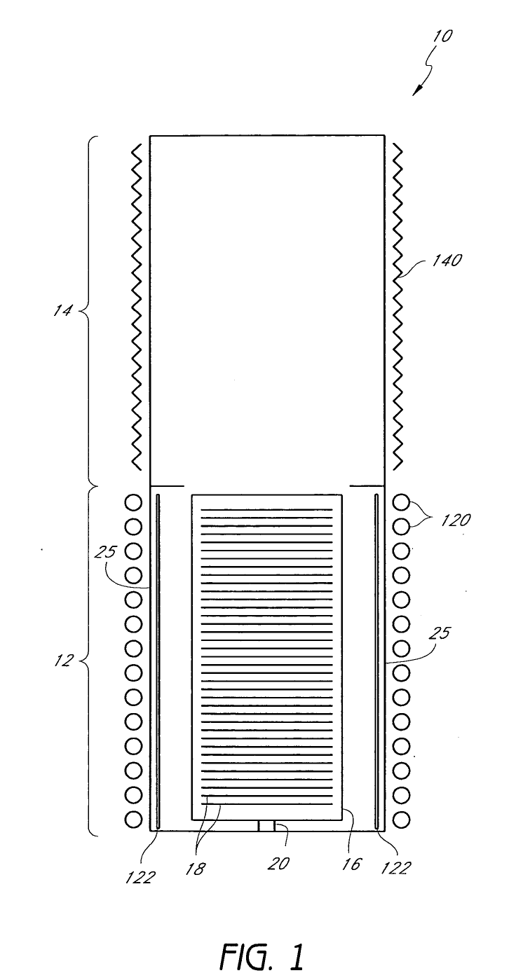

FIG. 1 illustrates an embodiment of a reactor 10 with separate resistive heating and radiant heating zones. In the embodiment illustrated in FIG. 1, the reactor 10 comprises a vertical furnace with a first processing zone 12 below a second processing zone 14 above the first processing zone 12. It will be appreciated that the second processing zone 14 may alternatively be below or on one side of the first processing zone 12 (e.g., a horizontal furnace). The reactor 10 further comprises a wafer handling area 28 in communication with the first processing zone 12. The reactor 10 may perform multiple processes in each processing zone 12, 14 but is preferably configured to perform hydrogen baking in the first processing zone 12 and epitaxial deposition in the second processing zone 14.

The reactor 10 further comprises a support 16 for holding a plurality of workpieces 18. In some embodiments, the support 16 is removable from the reactor 10. The support 16 can comprise a material that absorbs heat, for example solid silicon-carbide (SiC), graphite coated with SiC, or other suitable materials. Alternatively, the support 16 may be formed of a material that is transparent to radiant heat, such as quartz.

The workpieces 18 are typically semiconductor substrates, for example silicon wafers. The workpieces 18 are preferably 50 to 450 mm in diameter. In some embodiments, the workpieces 18 include a plurality of patterned layers, such as dielectric layers, conductive layers, and semiconductive layers.

In the first processing zone 12, the reactor 10 is heated with one or more radiant heating elements 120. The radiant heating elements 120 preferably comprise radiant heat lamps, for example tungsten halogen lamps. In a preferred embodiment, the heat lamps substantially surround the first processing zone 12. In some embodiments, for example the embodiment illustrated in FIG. 1, the radiant heating elements 120 are located outside of the reactor walls 25 that define the first processing zone 12. In the illustrated embodiment, the radiant heating elements 120 direct energy onto a black body 122 configured to regenerate heat to the workpieces 18. The black body 122 can be either within or outside of the reactor walls 25. Preferably, the black body 122 is located between the radiant heating elements 120 and the first processing zone 12. The black body 122 is preferably thin such that it may heat up and cool down quickly. The black body 122 may comprise, for example and without limitation, a SiC envelope substantially surrounding the workpieces 18.

The second processing zone 14 is defined by reactor walls 26 and is heated with resistive heating elements 140. The resistive heating elements 140 may comprise a resistive heating wire, for example made of a refractory silicide such as MoSi₂. In a preferred embodiment, the heating wire is coiled and substantially surrounds the second processing zone 14. The resistive heating elements 140 can be either within or outside of the reactor walls 26. Preferably, the resistive heating elements 140 are located outside of the reactor walls 26.

The reactor 10 comprises an apparatus 20 for moving the support 16 between the first processing zone 12 and second processing zone 14. The apparatus 20 may be a push rod, a specialized robot, etc. In embodiments in which the reactor 10 is a vertical furnace, the apparatus 20 is preferably configured to move the support 16 vertically through the reactor 10.

In certain embodiments, the workpieces 18 are HF dipped (etched) and placed into a nitrogen-purged work-in-progress (WIP) area prior to being loaded into the reactor 10. As described above, a HF dip removes oxide and results in hydrogen termination on the surfaces of the workpieces 18.

The workpieces 18 are loaded into or onto the support 16. In some embodiments, the workpieces 18 are loaded into or onto the support 16 when the support 16 is located in the first processing zone 12. In other embodiments, the workpieces 18 are loaded into or onto the support 16 in an area separate from the first processing zone 12 (e.g., the wafer loading area 28), and the support 16 is then moved into the first processing zone 12. Preferably, the first processing zone 12 is initially at a temperature that both maintains the hydrogen termination on the surfaces of workpieces 18 and removes moisture from the support 16 and the environment in a relatively short duration (e.g., less than five minutes), for example about 101 to 526° C., more preferably about 300 to 500° C., or even more preferably about 375 to 400° C. The loading temperature is preferably near the upper end of the preferred temperature ranges if the subsequent processing will be at a warmer temperature, in order to shorten the heating duration. The loading temperature is preferably near the lower end of the preferred temperature ranges if the subsequent processing will be at a cooler temperature in order to shorten the cooling duration. It will be appreciated that lower temperatures drive off less moisture than higher temperatures, so loading at lower temperatures may increase in the duration during which moisture is driven off. Hydrogen gas (e.g., ultra pure hydrogen gas) may flow through the first processing zone 12 and the reactor 10 during the loading sequence in order to minimize the growth of sub-oxide.

In certain embodiments, processing in the first processing zone 12 comprises “cleaning” the workpieces 18 to remove oxide, for example with a hydrogen bake, and processing in the second processing zone 14 comprises depositing one or more material layers onto the workpieces 18, for example with epitaxial deposition. The first processing zone 12 is preferably rapidly heated (e.g., at about 180 to 220° C./min) from the loading temperature to a hydrogen baking temperature, for example 750 to 800° C. In embodiments in which the workpieces 18 are etched with HF prior to processing in the first processing zone 12, a sub-oxide typically forms on the surfaces of the workpieces 18 as a result of interaction with moisture and oxygen in the atmosphere, for example to a thickness of less than about 1 Å and a surface density of approximately 10¹³ oxygen atoms/cm². In order to remove the sub-oxide, the workpieces 18 are preferably hydrogen baked at the hydrogen baking temperature. In some embodiments, hydrogen baking for about 15 minutes at 750° C. substantially removes the sub-oxide. Those of skill in the art will appreciate that longer durations at lower temperatures or shorter durations at higher temperatures may also be used. Temperature uniformity is relatively less important for hydrogen baking, so temperature variations induced by the use of radiant heating elements 120 in the first processing zone 12 will not have a negative impact on the resulting epitaxial interface on the surfaces of the workpieces 18 (i.e., the temperature is sufficiently uniform to remove the sub-oxide). Because the temperature of the hydrogen bake is typically greater than 527° C., the hydrogen bake also removes the hydrogen termination, leaving the surfaces of the workpieces 18 highly reactive. Rapid heating and cooling of the workpieces 18 within the first processing zone 12 minimizes the duration that the reactive surfaces of the workpieces 18 are exposed prior to subsequent deposition in the second processing zone 14. This provides for an improved epitaxial interface because the surfaces of the workpieces 18 have less of a chance to react with the environment. The cleaning preferably achieves a substantially oxygen-free and carbon-free interface on the surfaces of the workpieces 18.

After the hydrogen bake, the temperature in the first processing zone 12 can be quickly cooled (e.g., at about 40 to 60° C./min) to about the deposition temperature, for example to about 450 to 750° C. Fast cooling facilitated by using the radiant heating elements 120 helps to prevent contaminant buildup on the reactive surfaces of the workpieces 18 in the first processing zone 12 and helps to prevent devitrification of the support 16. The first processing zone 12 is preferably continuously purged with hydrogen (e.g., ultra pure hydrogen) during the cool-down sequence in order to avoid reoxidizing the surfaces of the workpieces 18 before deposition.

The workpieces 18 are preferably cooled to about the deposition temperature in the first processing zone 12 before they are moved into the second processing zone 14. The workpieces 18 are preferably moved from the first processing zone 12 into the second processing zone 14, after cleaning and cooling. The second processing zone 14 is preferably maintained at a generally uniform and constant deposition temperature, for example between about 450 and 750° C., by resistive heating elements 140. In a preferred embodiment involving the deposition of undoped epitaxial silicon, the temperature in the second processing zone 14 is between about 650 and 700° C. The temperature in the second processing zone 14 can be allowed to stabilize after the addition of the workpieces 18, for example for about 10 minutes. One or more material layers, for example an epitaxial layer, can be deposited on the workpieces 18 by introducing process gases into the reactor 10. The duration of the deposition varies based on the desired thickness and number of the deposited material layers, temperature, pressure, etc. For example, thicker layers and lower temperatures increase epitaxial deposition durations. In some embodiments, the deposition duration is about 25 minutes. Preferably, the temperature in the second processing zone 14 does not substantially change during processing.

After deposition in the second processing zone 14, the support 16 can be moved back into the first processing zone 12 by the apparatus 20 for subsequent cooling using radiant heating elements 120. This sequence of steps allows the second processing zone 14 to stay at about a constant temperature. The resistive heating elements 140 in the second processing zone 14 are suitable for maintaining substantially stable and uniform temperature, as described above.

One aspect of the present invention is recognition of the interaction between loading conditions and processing times. The reactivity of the surfaces of the workpieces 18 is a function of temperature, so loading the workpieces 18 at high temperatures in air comprising oxygen (e.g., in the form of water vapor) produces thick sub-oxides (i.e., surface densities greater than about 10¹⁵ atoms/cm²). Moreover, hydrogen bake temperature is a function of the sub-oxide thickness. For example, a hydrogen bake at about 750° C. cannot remove sub-oxide with a surface density of about 10¹⁴ atoms/cm², but a hydrogen bake at about 900° C. can remove sub-oxide at that concentration. Higher hydrogen bake temperatures are problematic for a number of reasons. First, higher hydrogen bake temperatures require longer ramp-up and cool-down durations, which decreases the throughput through the reactor. It will be appreciated that this problem is mitigated to some extent by using radiant heating rather than resistive heating. Second, higher hydrogen bake temperatures may also cut into the thermal budget of the workpieces 18. Third, at certain temperatures, the oxide becomes so thick that hydrogen termination is effectively lost, causing the surfaces of the workpieces 18 to be even more reactive with oxygen in the air, thereby forming sub-oxides that are too thick to be removed by a hydrogen bake at any temperature (e.g., surface densities greater than about 10¹⁵ atoms/cm²). Higher hydrogen bake temperatures may expose the surfaces of the workpieces 18 to these certain temperatures.

In order to reduce exposure of the surfaces of the workpieces 18 to oxygen in the air, traditional reactors typically employ a load lock that reduces the number of molecules of air with which the surfaces of the workpieces 18 may react. For example, a traditional reactor may comprise a roughing pump that can reduce the pressure in a wafer loading area to about 10⁻³ Torr. However, at pressures of about 10⁻³ Torr and high temperatures, the interaction between the surfaces of the workpieces 18 and oxygen in the air produces oxides at concentrations greater than about 10¹⁴ atoms/cm². As such, the maximum loading temperature at about 10⁻³ Torr is between about 250 and 350° C.

As described above, the workpieces 18 are preferably loaded at the higher end of the temperature ranges, which removes moisture but preserves hydrogen termination when subsequent processing steps, such as hydrogen bake and epitaxial deposition, are performed at higher temperatures, in order to minimize the ramp-up and cool-down durations. In order to load at high end temperatures such as 350 to 526° C., conventional reactors reduce the pressure in a load lock to about 10⁻⁸ Torr in order to mitigate the amount of oxygen in the air that can form oxide on the surfaces of the workpieces 18. The ability to produce such low pressures typically adds substantial cost to the system (e.g., comprising greater than 20% of the overall cost of the system). An additional apparatus for pressure reduction, which is typically included between the load lock and the process chamber, can increase the footprint of the apparatus. Moreover, even at low pressures, the surfaces of the workpieces 18 are highly reactive once hydrogen termination has been removed (e.g., once the temperature exceeds about 527° C. in the ramp-up to the hydrogen bake temperature), causing potential contamination during the ramp-up and cool-down durations due to impurities remaining in the apparatus.

In certain alternative embodiments, the reactor 10 comprises a nitrogen-purged wafer handling area rather than a load lock. Purging with a dry, preferably purified, inert gas (e.g., nitrogen gas) during loading substantially decreases the amount of oxygen with which the surfaces of the workpieces 18 may react. Rather than decreasing the total number of molecules that can interact with the workpieces 18, as in a load lock, the composition of the molecules that can interact with the workpieces 18 is changed to reduce the amount of oxygen. The lack of oxygen in a purged wafer handling area enables the use of high end loading temperatures (e.g., between about 350° C. and 526° C.) and high loading pressures (e.g., about 10⁻³ Torr) without causing the growth of thicker native oxides. Without thicker native oxides, the hydrogen bake temperature may remain low (e.g., at about 750° C.), thereby avoiding the disadvantages of high hydrogen bake temperatures discussed above. Furthermore, the efficacy of hydrogen baking does not depend heavily on pressure, so the high pressure as a result of the lack of a load lock does not adversely affect processing.

When the temperature of the workpieces 18 increases during the ramp-up to the hydrogen bake temperature, the surfaces of the workpieces 18 lose their hydrogen termination, thereby becoming highly reactive to any potential oxidizing species. The use of radiant heating elements 120 in the first processing zone 12 decreases the duration that the workpieces 18 are in the highly reactive state because the ramp-up and cool-down durations are much lower than the ramp-up and cool-down durations in a traditional resistively-heated reactor, thereby substantially reducing the risk of contamination.

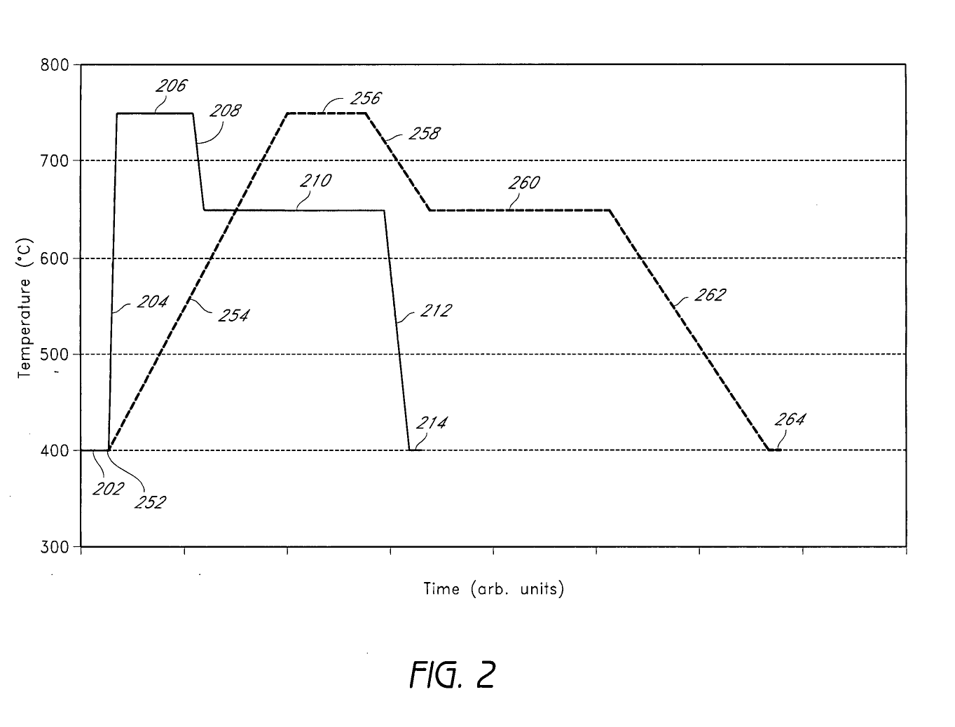

FIG. 2 is a process chart of temperature (in degrees Celsius) versus time (in arbitrary units) for an exemplary process including a hydrogen bake and an epitaxial deposition. The dashed line represents the process as performed in a conventional resistively-heated reactor and the solid line represents the process as performed in the reactor 10 of FIG. 1. The lines 202, 252 are the duration of loading the workpieces 18 into the support 16, which is about the same for both reactors. In the illustrated process, the workpieces 18 are loaded at about 400° C., which is cool enough to maintain hydrogen termination but hot enough to drive moisture from the workpieces 18 and the support 16. The workpieces 18 are then heated to the temperature at which the hydrogen bake is performed, for example about 750° C. In the reactor 10 of the present application, the heating 204 occurs in the first processing zone 12. The heating rate represented by the line 204 is much steeper than in the heating rate represented by the line 254 because heating with radiant heating elements is quicker than heating with resistive heating elements. The lines 206, 256 represent the duration of a hydrogen bake at about 750° C., which is about the same for both reactors. The workpieces 18 are then cooled to about the temperature at which the deposition will be performed, for example about 650° C. The cooling rate represented by the line 208 is much steeper than the cooling rate represented by the line 258 because cooling with radiant heating elements is quicker than cooling with resistive heating elements.

In the reactor 10 of the present application, the line 210 represents the duration during which a number of steps occur, including moving the workpieces 18 into the second processing zone 14, allowing the temperature of the workpieces 18 to stabilize in the second processing zone, depositing one or more material layers on the workpieces 18 while in the second processing zone 14, and moving the workpieces 18 back into the first processing zone 12. In embodiments in which epitaxial deposition is performed at low pressure, the line 210 may include pumping the second processing zone 14 down to the deposition pressure. In other embodiments, the line 202 includes decreasing pressure to the deposition pressure because hydrogen baking is not highly dependent on pressure. The line 260 of the conventional process represents the duration during which the temperature is allowed to stabilize and one or more material layers are deposited onto the workpieces 18. The deposition durations represented in the lines 210 and 260 are about the same for both reactors, but stabilization time may be faster for the reactor 10 with separate processing zones because the temperature in the second processing zone 14 can remain constant while the workpieces 18 are processed at different temperatures in the first processing zone 12. The workpieces 18 are then cooled to an unloading temperature, for example about 400° C. The cooling rate represented by the line 212 is much steeper than in the cooling rate represented by the line 262 because cooling associated with radiant heating is quicker than cooling associated with resistive heating. The lines 214, 264 are the duration of unloading the workpieces 18 from the support 16, which is about the same for both reactors. The differences in heating and cooling times, which are the result of the use of separate resistive and radiant heating zones, provides faster throughput for the reactor 10 depicted in FIG. 1 than for a conventional resistively-heated reactor. In some embodiments, the total process time in a reactor with separate resistive and radiant heating zones is about one half the total process time in a conventional reactor.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while several variations of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the disclosed invention. Thus, it is intended that the scope of the present invention herein disclosed should not be limited by the particular disclosed embodiments described above, but should be determined only by a fair reading of the claims that follow.

What is claimed is:

1. A reactor for processing a plurality of workpieces, comprising:
a support for holding the plurality of workpieces;
a first processing zone;
one or more radiant heating elements adapted to heat a plurality of workpieces positioned in the first processing zone;
a second processing zone;
one or more resistive heating elements adapted to heat a plurality of workpieces positioned in the second processing zone; and
an apparatus for moving the support between the first processing zone and the second processing zone.

2. The reactor of claim 1, wherein the first and second processing zones are defined within a horizontal furnace and wherein the apparatus for moving the support is configured to move the support laterally through the furnace.

3. The reactor of claim 1, wherein the first and second processing zones are defined within a vertical furnace and wherein the apparatus for moving the support is configured to move the support vertically through the furnace.

4. The reactor of claim 1, wherein the one or more radiant heating elements are outside of reactor walls that define the first processing zone.

5. The reactor of claim 1, further comprising a black body between the one or more radiant heating elements and the first processing zone.

6. The reactor of claim 5, wherein the black body comprises a silicon-carbide envelope substantially surrounding the first processing zone.

7. The reactor of claim 1, further comprising a wafer handling area configured to be purged with inert gas.

8. The reactor of claim 1, further comprising a wafer handling area configured to be purged with nitrogen gas.

9. A method of processing a plurality of workpieces, comprising:
providing the workpieces in a first processing zone;
providing radiant heat to the workpieces in the first processing zone;
processing the workpieces in the first processing zone;
after processing the workpieces in the first processing zone, moving the workpieces to a second processing zone;
providing resistive heat to the workpieces in the second processing zone; and
processing the workpieces in the second processing zone.

10. The method of claim 9, wherein the providing the workpieces comprises:
loading the workpieces into the first processing zone; and
during the loading, purging the first processing zone with inert gas.

11. The method of claim 9, wherein the providing the workpieces comprises:
loading the workpieces into the first processing zone; and
during the loading, purging the first processing zone with nitrogen gas.

12. The method of claim 9, wherein the processing in the first processing zone comprises cleaning the workpieces and wherein the processing in the second processing zone comprises depositing one or more material layers onto the workpieces.

13. The method of claim 12, wherein the cleaning comprises conducting a hydrogen bake and the depositing comprises epitaxial deposition.

14. The method of claim 12, wherein the cleaning removes oxide from the workpieces.

15. The method of claim 12, wherein the cleaning results in the surfaces of the workpieces being substantially free of oxygen and carbon.

16. The method of claim 9, further comprising etching the workpieces with hydrofluoric acid before the providing the workpieces in the first processing zone.

17. The method of claim 9, wherein providing the workpieces in the first processing zone comprises loading the workpieces into the first processing zone at a temperature selected to maintain hydrogen termination on the surfaces of the workpieces.

18. The method of claim 9, wherein providing the workpieces in the first processing zone comprises loading the workpieces into the first processing zone at a temperature between about 101 and 526° C.

19. The method of claim 9, wherein providing the workpieces in the first processing zone comprises loading the workpieces into the first processing zone at a temperature between about 375 and 400° C.

20. The method of claim 9, wherein providing radiant heat to the workpieces in the first processing zone comprises heating the workpieces at a rate of between about 180 and 220° C. per minute.

21. The method of claim 9, wherein processing in the first processing zone comprises cooling the workpieces at a rate between about 40 and 60° C. per minute.

22. The method of claim 12, wherein the cleaning is conducted at a temperature between about 750 and 800° C. and wherein the depositing of one or more material layers is conducted at a temperature between about 450 and 750° C.

23. The method of claim 22, wherein the depositing of one or more material layers is conducted at a temperature between about 650 and 700° C.

24. The method of claim 12, wherein processing in the first processing zone further comprises, after the cleaning step, cooling the workpieces to about a temperature selected for the depositing step in the second processing zone.

25. The method of claim 9, further comprising moving the workpieces to the first processing zone after processing the workpieces in the second processing zone.

26. The method of claim 25, further comprising adjusting the temperature of the workpieces in the first processing zone after processing the workpieces in the second processing zone.
